(19) United States
(12) Patent Application Publication
(10) Pub. No.: US 2011/0103077 A1
(43) Pub. Date: May 5, 2011

(54) LIGHT EMITTING DIODE PACKAGING METHOD WITH HIGH LIGHT EXTRACTION AND HEAT DISSIPATION USING A TRANSPARENT VERTICAL STAND STRUCTURE

(75) Inventors: Chih-Chien Pan, Goleta, CA (US); Jun Seok Ha, Goleta, CA (US); Steven P. DenBaars, Goleta, CA (US); Shuji Nakamura, Santa Barbara, CA (US); Junichi Sonoda, Kanagawa (JP)

(73) Assignee: THE REGENTS OF THE UNIVERSITY OF CALIFORNIA, Oakland, CA (US)

(21) Appl. No.: 12/908,793

(22) Filed: Oct. 20, 2010

Related U.S. Application Data
(60) Provisional application No. 61/258,056, filed on Nov. 4, 2009.

(51) Int. Cl. F21V 29/00; H05K 13/00

(52) U.S. Cl. 362/373; 29/592.1

(57) ABSTRACT

A packaging method for light emitting diodes provides both high light extraction and heat dissipation using a transparent vertical stand structure. A light emitting diode (LED) is attached to a vertical stand structure for supporting the LED, wherein the LED is bonded to the vertical stand structure, so that one of the LED's sides faces vertically upwards, another of the LED's sides faces vertically downwards, a top surface of the LED faces horizontally sideways in one direction, and a bottom surface of the LED faces horizontally sideways in another direction. The vertical stand structure comprises a connecting stem between the LED and a header, and is made of a material that provides for heat dissipation and may also be transparent to light generated in the LED, such as sapphire or zinc oxide. The LED and the vertical stand structure may be encapsulated within a mold.

### CROSS REFERENCE TO RELATED APPLICATIONS

This application claims priority under 35 U.S.C. §119(e) to co-pending and commonly-assigned U.S. Provisional Patent Application Ser. No. 61/258,056, entitled “LED PACKAGING METHOD WITH HIGH LIGHT EXTRACTION AND HEAT DISSIPATION USING A TRANSPARENT VERTICAL STAND STRUCTURE,” filed on Nov. 4, 2009, by Chih Chien Pan, Jun Seok Ha, Steven P. DenBaars, Shuji Nakamura, and Junichi Sonoda, attorney's docket number 30794.335-US-P1, which application is incorporated by reference herein.

### BACKGROUND OF THE INVENTION

1. Field of the Invention

This invention relates to a packaging method for light emitting diodes (LEDs) providing for improved light extraction and heat dissipation using a transparent vertical stand structure.

2. Description of the Related Art

For commercial LEDs, it is important to emit more photons to free space for high output power. In order to achieve this goal, the LED packaging method should be taken into account carefully. There exist two important factors in the packaging of the bright light emitting diodes (LEDs): (1) high light extraction, and (2) sufficient heat dissipation.

For example, FIG. 1 shows a conventional LED packaging method, wherein the LED chip or die 100 is mounted on a metal header 102 by bonding with an Si or Ag paste. The LED die 100 is then wire bonded 104 to two posts 106 that serve as electrical leads. The LED die 100 is encapsulated within a mold 108 having an truncated inverted cone shape and emits light from the top surface of the LED die 100 upwards out of the mold 108, as represented by the arrow labeled “Light.” This packaging method results in good heat dissipation, but it does not satisfy the function of higher light extraction. However, with this packaging method, the light output power emitted from an active region of the LED 100 could fade and be absorbed during the reflection between the header 102 and the LED die 100 inside.

In order to decrease the output power loss, recently there was the introduction of a “suspended packaging” method, as shown in FIG. 2. This method suspends an LED die 200 from a header 202 using only two connecting Au wires 204 that are attached to two posts 206, which serve as electrical leads. The LED die 200 is encapsulated within a mold 208 having an truncated inverted cone shape and emits light from the top surface of the LED die 200 laterally to the sides of the mold 208, as represented by the arrows labeled “Light.” This method is reported to have improved light extraction efficiency, but the suspended packaging method cannot effectively transfer heat from the active region of the LED 200, because the heat can only be dissipated through the two connecting Au wires 204. The accumulated heat has the disadvantage of reducing the reliability of the LED 200, as well as degrading the encapsulant 208 and any phosphors used with the LED 200, which could result in lower output power.

Therefore, it is necessary to develop a new packaging method with improved light extraction and sufficient heat dissipation. The present invention satisfies this need.

### SUMMARY OF THE INVENTION

To overcome the limitations in the prior art described above, and to overcome other limitations that will become apparent upon reading and understanding the present specification, the present invention discloses a packaging method for light emitting diodes provides both high light extraction and heat dissipation using a transparent vertical stand structure.

A light emitting diode (LED) is attached to a vertical stand structure for supporting the LED, wherein the LED is bonded to the vertical stand structure, so that one of the LED's sides faces vertically upwards, another of the LED's sides faces vertically downwards, a top surface of the LED faces horizontally sideways in one direction, and a bottom surface of the LED faces horizontally sideways in another direction.

The vertical stand structure comprises a connecting stem between the LED and a header, and is made of a material that provides for heat dissipation. This material may also be transparent to light generated in the LED. For example, the vertical stand structure may be comprised of sapphire or zinc oxide (in the form of substrates).

Both the LED and the vertical stand structure are encapsulated within a mold, and the LED is attached to the vertical stand structure, so that one of the LED's sides faces vertically upwards to a top surface of the mold, another of the LED's sides faces vertically downwards to a bottom surface of the mode, the top surface of the LED faces horizontally sideways in one direction to one side of the mold, and the bottom surface of the LED faces horizontally sideways in another direction to another side of the mold. In one embodiment, the mold is a truncated inverted cone shape, although other shapes may be used.

### BRIEF DESCRIPTION OF THE DRAWINGS

Referring now to the drawings in which like reference numbers represent corresponding parts throughout:

FIG. 1 shows a conventional LED packaging method.

FIG. 2 shows a suspended LED packaging method.

FIGS. 3(a) and 3(b) illustrate alternative embodiments of an LED packaging method according to the present invention, wherein FIG. 3(a) shows a vertical stand structure comprised of a sapphire substrate and FIG. 3(b) shows a vertical stand comprised of a surface textured ZnO bulk substrate.

FIG. 4 is a SEM (scanning electron microscope) image showing hexagonal pyramids on the ZnO surface.

FIG. 5 is a flow chart of the vertical stand packaging method according to the present invention.

FIG. 6 is an optical micrograph that shows light emitted to both lateral directions of the LED.

FIG. 7 shows the packaging factors for different packaging types using LED chips on bulk c-plane (0001).

FIG. 8 shows the packaging factors for different packaging types using LED chips on semipolar (11-22).

FIG. 9 shows the Current-Voltage curves for suspended packaging, vertical stand packaging with sapphire, and vertical stand packaging with ZnO bulk substrate.

FIG. 10 is a graph of the External quantum efficiency v. Current properties for suspended packaging, vertical stand packaging with sapphire, and vertical stand packaging with ZnO bulk substrate.

FIG. 11 illustrates using direct wafer bonding process to modify the vertical stand packaging with the ZnO bulk substrate.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

The present invention comprises a new packaging method that satisfies the two important factors of improved light extraction and sufficient heat dissipation at the same time.

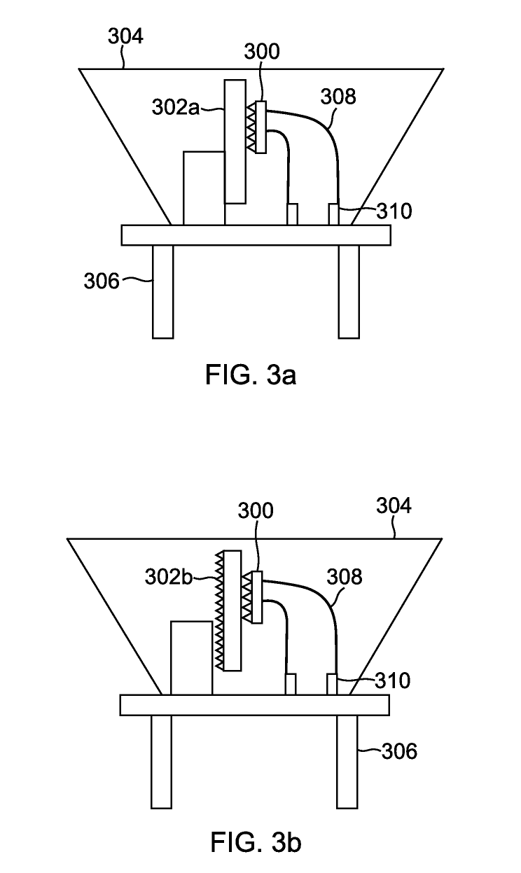

FIGS. 3(a) and 3(b) illustrate alternative embodiments of an LED packaging method and apparatus according to the present invention. As shown in FIGS. 3(a) and 3(b), this new packaging method and apparatus comprises an LED die 300, a vertical stand structure 302a, 302b for supporting the LED die 300, and a silicone mold 304 having a truncated inverted cone shape, wherein FIG. 3(a) shows a vertical stand structure 302a comprised of a sapphire substrate and FIG. 3(b) shows a vertical stand structure 302b comprised of a surface textured ZnO bulk substrate. The vertical stand structure 302a, 302b acts a connecting stem between the LED 300 and a header 306. The LED die 300 is rotated before being bonded to the vertical stand structure 302a, 302b using an Si or Ag paste, and both the LED die 300 and the vertical stand structure 302a, 302b are encapsulated within the mold 304, so that one of the sides of the LED die 300 faces vertically upwards to the top surface of the mold 304, another of the sides of the LED die 300 faces vertically downwards to a bottom surface of the mold 304, the top surface of the LED die 300 faces horizontally sideways in one direction to one side of the mold 304, and the bottom surface of the LED die 300 faces horizontally sideways in another direction to another side of the mold 304. In each instance, the LED die 300 is connected to a header 306 using two connecting wires 308 that are attached to two posts 310, which serve as electrical leads. The LED die 200 may emit light from its top surface, bottom surface and/or side surfaces.

This orientation of the LED die 300 in FIGS. 3(a) and 3(b) is similar to the orientation of the LED die in the suspended packaging method of FIG. 2, and results in higher light extraction efficiency. However, unlike the suspended packaging method of FIG. 2, the LED die 300 in FIGS. 3(a) and 3(b) is not suspended using wires 308, but instead is bonded to the vertical stand structure 302a, 302b, which is comprised of materials chosen for their heat dissipation properties. These vertical stand structure 302a, 302b materials may also be transparent to the light generated in the LED 300.

As noted above, in the embodiment described herein, sapphire and ZnO bulk substrates are used for the vertical stand structures 302a and 302b, respectively. However, other materials may also be used, such as GaN or various other transparent materials. Materials with high refractive index are also preferable for light extraction purposes.

These sapphire and ZnO bulk substrates both provide a heat dissipation path and a light extraction medium. Using the present invention, a much higher value of a packaging factor is obtained, as well as good properties at a high current injection.

Experimental results with the present invention show an increase in the light extraction efficiency, so that the packaging factor was improved to 1.43 for LEDs on a (0001) plane GaN substrate and 1.37 for LEDs on a semi-polar (11-22) plane GaN substrate, while conventional packaging has a packaging factor of 1.13. Also, experimental results confirm that this new packaging method has higher external quantum efficiency (EQE) at a higher driving current than the suspended packaging method, because of better dissipation of generated heat from the LED die.

Fabrication Process

The following describes the fabrication process associated with the present invention.

LED Growth and Processing

The LEDs were grown on various planes of GaN bulk substrates, supplied by Mitsubishi Chemical Corporation, with conventional metal-organic chemical vapor deposition. The LEDs were fabricated by a usual fabrication process for lateral type LEDs. The mesa area was 290 μm×490 μm. An ITO layer of 250 nm was deposited for the p-type transparent contact layer. The n-contacts comprised a Cr/Ni/Au metal stack deposited on the n-GaN. A thick Ti/Au stack of 10/300 nm was deposited on the thin metal to act as a bonding pad.

LED Mounting on a ZnO Bulk Substrate

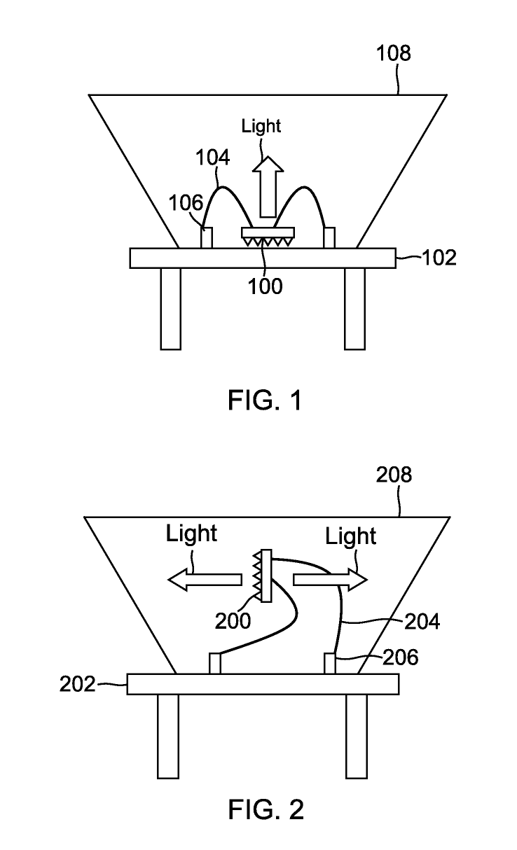

After finishing the LED fabrication process, the LED wafer was scribed into individual small chips. These LED chips were mounted on each structure. For a comparison of the respective packaging factors, which indicate the improvement in output power, experiments were performed using a conventional packaging method, as shown in FIG. 1, and a suspended packaging method, as shown in FIG. 2, as well as the new vertical stand packaging method of the present invention, as shown in FIGS. 3(a) and 3(b). For the vertical stand packaging method of the present invention, the experimental results used two types of materials for the vertical stand structures: (1) sapphire and (2) ZnO bulk substrate.

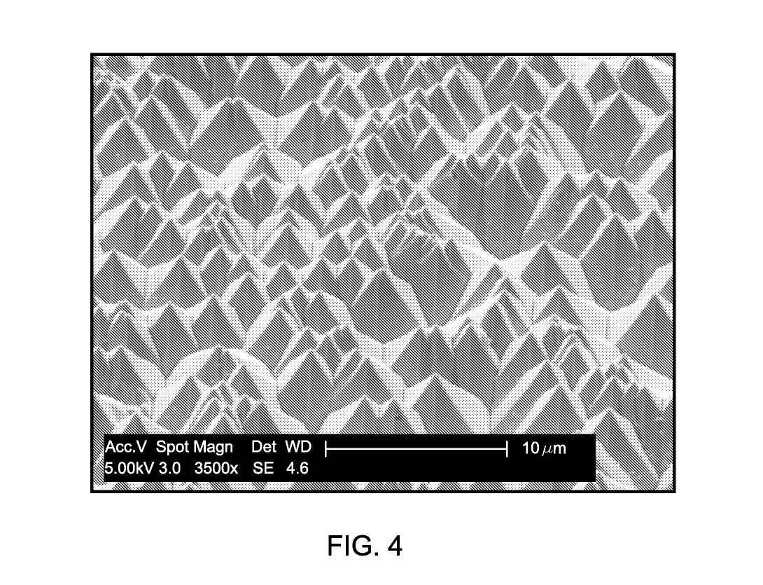

The ZnO substrate was selected for several reasons. First, ZnO has much higher thermal conductivity than sapphire substrates, so better heat dissipation can be expected. Second, ZnO has a wide band gap energy and high refractive index than other materials, so that the light generated in the active area of GaN/InGaN based LEDs could be extracted easily without absorption in the substrate itself. Third, the ZnO has higher reflective index, which helps to make the critical angle and escape cone large to obtain a much higher extraction efficiency. Finally, ZnO material is very easily etched using various etchants, resulting in much higher extraction efficiency through the formation of surface texturing. FIG. 4 shows an exemplary hexagonal pyramidal surface morphology of an ZnO layer etched by dilute acid (HCl:H2O=1:10) for 1 minute.

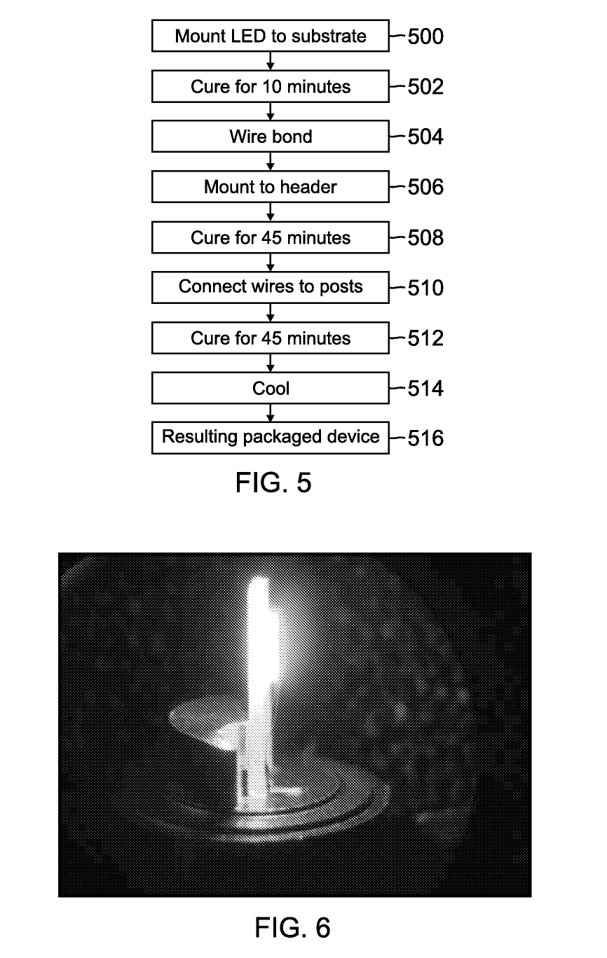

The fabrication procedure of the vertical stand packaging method of the present invention is illustrated in FIG. 5. After surface texturing the ZnO bulk substrate, the LED is mounted with silicone to the Zn face of the ZnO bulk substrate (500). After mounting, the device is placed into an oven to cure it for 10 minutes (502). After curing, a wire bonder is used to place two long Au wires on both nip pads of the device (504). An Ag paste with high thermal conductivity is placed on the heat sink of the header and the device is mounted on the header using the paste (506). Thereafter, the device is put back into the oven for curing for 45 minutes (508). When the device is stabilized on the header, an Ag paste is used to connect two wires on both posts (510), and the device is cured in the oven for another 45 minutes (512). Thereafter, the device is removed from the oven and cooled for approximately 30 minutes to ensure that there are no other heat effects during the measurements (514). The end result is the packaged device (516). After packaging, the light can be seen emitting in both lateral directions using an optical microscope, as shown in FIG. 6.

Device Properties

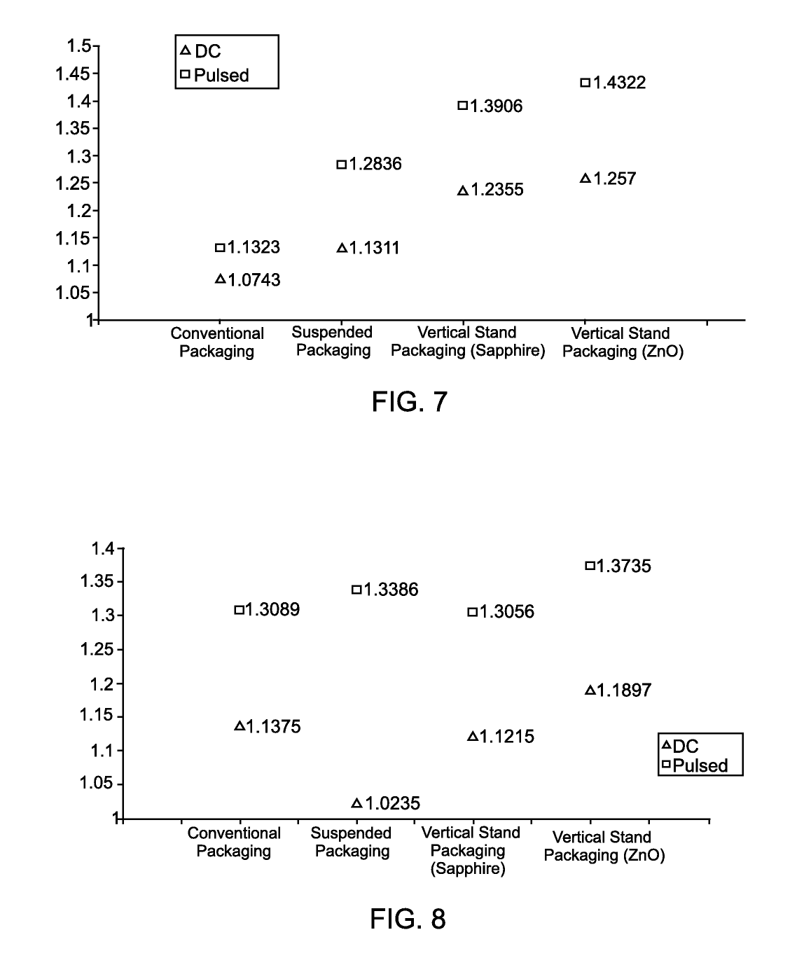

FIG. 7 shows the packaging factors for different packaging types using LED chips on (0001) bulk GaN substrates and FIG. 8 shows the similar properties on (11-22) bulk GaN substrates. The first is a conventional packaging method that mounts chip on a header (see FIG. 1) and the second is a suspended packaging method (see FIG. 2). The third and fourth are the vertical stand packaging method of the present invention with a sapphire substrate (see FIG. 3(a)) and with a surface textured ZnO bulk substrate (see FIG. 3(b)), respectively. All packaging types were encapsulated in a silicone mold having a truncated inverted cone shape. The optical output powers were measured both as DC and pulsed (10% duty cycle). From these results, it can be determined that the vertical stand packaging method of the present invention has the best packaging factors for both DC and pulsed measurements. This means that the vertical stand packaging method is expected to provide the best optical efficiency and device performance.

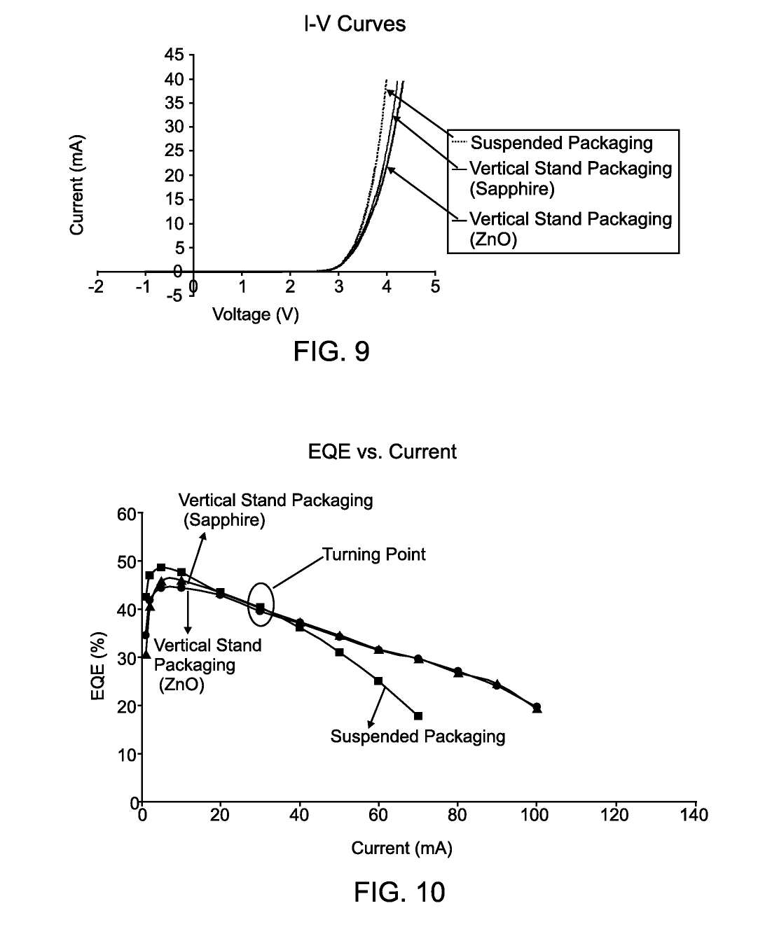

In addition, in order to prove this vertical stand packaging has good heat sinking properties, current-voltage (I-V) characteristics were measured for each type, and the results are shown in FIG. 9. It is convenient that the suspended packaging method and the vertical stand packaging method using the ZnO bulk substrate had the smallest and largest series resistance, respectively. These data mean that the latter has the lowest junction temperature this case. In addition, from the measurement of external quantum efficiency (EQE) for three types, as shown in FIG. 10, it can be seen that the EQE of the LED with the suspended packaging method dropped faster than those of the other two packaging method at higher current injection. It is thought that the heat can not transfer easily in the suspended package method, so that the high junction temperature increases non-radiative recombination. Conversely, the vertical stand packaging method provides good the thermal dissipation properties.

From these two experimental results, it is known that the vertical stand packaging method has both good efficient extraction and better heat dissipative properties, which are regarded as two very important factors in packaging.

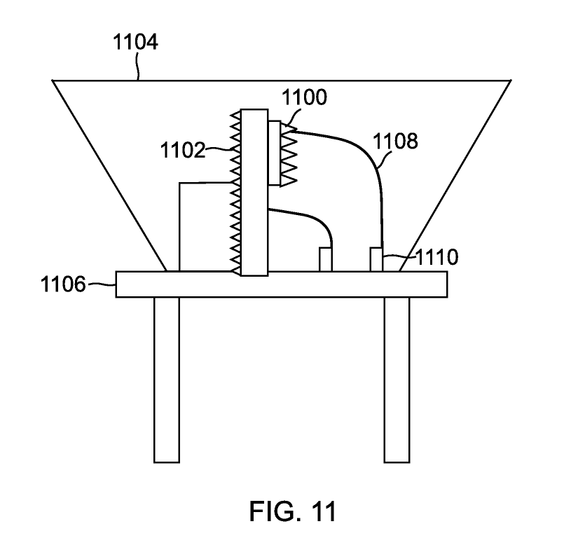

From the data mentioned above, it can be seen that there is not a significant difference in series resistance or EQE droop at high current injection between the package with sapphire substrate and the package with bulk ZnO. The silicone which is used for the bonding of LED chips to the vertical stand materials is thought to be the main factor for creating this phenomenon, because silicone has relatively worse thermal conductivity and became a bottleneck for successfully transferring heat from the LED to the heat sinks. Therefore, ZnO/GaN direct bonding can be used to improve vertical stand packaging with ZnO substrates as another vertical stand structure, as shown in FIG. 11, which illustrates an LED die 1100, a vertical stand structure 1102 for supporting the LED die 1100, and a silicone mold 1104 having a truncated inverted cone shape, wherein the LED die 1100 is connected to a header 1106 using two connecting wires 1108 that are attached to two posts 1110 as electrical leads. For this vertical stand structure, however, there is no need to put silicone between the LED die 1100 and the substrate comprising the vertical stand structure 1102.

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching. It is intended that the scope of the invention be limited not by this detailed description, but rather by the claims appended hereto.

What is claimed is:

1. A light emitting apparatus, comprising:
a light emitting diode (LED); and
a vertical stand structure for supporting the LED;
wherein the LED is attached to the vertical stand structure, so that one of the LED's sides faces vertically upwards, another of the LED's sides faces vertically downwards, a top surface of the LED faces horizontally sideways in one direction, and a bottom surface of the LED faces horizontally sideways in another direction.

2. The apparatus of claim 1, wherein the vertical stand structure is comprised of a material that provides for heat dissipation.

3. The apparatus of claim 1, wherein the vertical stand structure is transparent to light generated in the LED.

4. The apparatus of claim 1, wherein the vertical stand structure comprises a sapphire substrate or a zinc oxide substrate.

5. The apparatus of claim 1, wherein the LED is bonded to the vertical stand structure.

6. The apparatus of claim 1, wherein the vertical stand structure is a connecting stem between the LED and a header.

7. The apparatus of claim 1, wherein both the LED and the vertical stand structure are encapsulated within a mold, and the LED is attached to the vertical stand structure, so that one of the LED's sides faces vertically upwards to a top surface of the mold, another of the LED's sides faces vertically downwards to a bottom surface of the mode, the top surface of the LED faces horizontally sideways in one direction to one side of the mold, and the bottom surface of the LED faces horizontally sideways in another direction to another side of the mold.

8. The apparatus of claim 1, wherein the mold is a truncated inverted cone shape.

9. A method for packaging a light emitting apparatus, comprising:
attaching a light emitting diode (LED) to a vertical stand structure for supporting the LED, so that one of the LED's sides faces vertically upwards, another of the LED's sides faces vertically downwards, a top surface of the LED faces horizontally sideways in one direction, and a bottom surface of the LED faces horizontally sideways in another direction.

10. The method of claim 9, wherein the vertical stand structure is comprised of a material that provides for heat dissipation.

11. The method of claim 9, wherein the vertical stand structure is transparent to light generated in the LED.

12. The method of claim 9, wherein the vertical stand structure comprises a sapphire substrate or a zinc oxide substrate.

13. The method of claim 9, wherein the LED is bonded to the vertical stand structure.

14. The method of claim 9, wherein the vertical stand structure is a connecting stem between the LED and a header.

15. The method of claim 9, wherein both the LED and the vertical stand structure are encapsulated within a mold, and the LED is attached to the vertical stand structure, so that one of the LED's sides faces vertically upwards to a top surface of the mold, another of the LED's sides faces vertically downwards to a bottom surface of the mode, the top surface of the LED faces horizontally sideways in one direction to one side of the mold, and the bottom surface of the LED faces horizontally sideways in another direction to another side of the mold.

16. The method of claim 9, wherein the mold is a truncated inverted cone shape.
